(19) United States
(12) Patent Application Publication
(10) Pub. No.: US 2011/0085312 A1
(43) Pub. Date: Apr. 14, 2011

(54) COMPUTER HOST AND MOTHERBOARD USED IN THE COMPUTER HOST

(76) Inventors: Wei TANG, Taipei (TW); Chih-Hsieh Chen, Taipei (TW)

(21) Appl. No.: 12/637,902

(22) Filed: Dec. 15, 2009

(30) Foreign Application Priority Data
Oct. 12, 2009 (TW) 098134550

(51) Int. Cl. H05K 1/14

(52) U.S. Cl. 361/784

(57) ABSTRACT

A motherboard includes a square circuit board having an indention at a corner thereof. A memory module is disposed on the circuit board near the indention. A first I/O module is disposed on an edge of the circuit board near the indention. A chip module is disposed at an area of the circuit board away from the indention. The motherboard is fixed at a half portion of a chassis of a computer host. A heat dissipation unit is accommodated in the indention of the circuit board. The other half portion of the chassis accommodates a hard disk drive.

### BACKGROUND OF THE INVENTION

1. Technical Field

The invention generally relates to computers, particularly to computer hosts and motherboards.

2. Related Art

With advance of the semiconductor industry, computers tend to be more and more compact and light. Portable computers such as laptops are frequently weeded out by new models. Therefore, the development schedules of the portable computers are tight. The manufactures of computers must expect a motherboard which can be used in various models of productions.

Taiwan Patent No. 1296487 discloses a motherboard for a laptop. There is an indention in the circuit board of the motherboard. A first area and a second area are defined in a portion near the indention. A third area and a fourth area are defined in the other portion far from the indention. These areas are used for being mounted by CPU, memory, GPU and peripheral cards, respectively. The arrangement allows the motherboard can fit various CPUs and computer housings.

However, for satisfying requirements of consumers, some models may quip an optical disk drive, and some models may equip double hard disk drive. The abovementioned motherboard can not provide high compatibility for various productions. And the elements on the motherboard also lack selectivity and interchangeability. Thus the development period is hard to be shortened and the cost is hard to be lowered.

### SUMMARY OF THE INVENTION

A primary object of the invention is to provide an arrangement of motherboard with high compatibility, which can be applied in various models of motherboard and can shorten development period.

Another object of the invention is to provide an arrangement of computer host with high compatibility, which can be applied in a housing and can shorten development period.

Another object of the invention is to provide an arrangement of computer host with a free room which can accommodates various devices such as a wireless network device.

To accomplish the above objects, the motherboard of the invention includes a square circuit board having an indention at a corner thereof. A memory module is disposed on the circuit board near the indention. A first I/O module is disposed on an edge of the circuit board near the indention. A chip module is disposed at an area of the circuit board away from the indention. The motherboard is fixed at a half portion of a chassis of a computer host. A heat dissipation unit is accommodated in the indention of the circuit board. The other half portion of the chassis accommodates a hard disk drive.

### BRIEF DESCRIPTION OF DRAWING

FIG. 1 is a perspective view of the computer host with the motherboard of the invention;

FIG. 2 is a planar view of the motherboard of the invention;

FIG. 3 is a planar view of the second embodiment of the motherboard;

FIGS. 4 and 5 are two planar views of the computer host of the invention; and

FIG. 6 is a planar view of the second embodiment of the computer host.

### DETAILED DESCRIPTION OF THE INVENTION

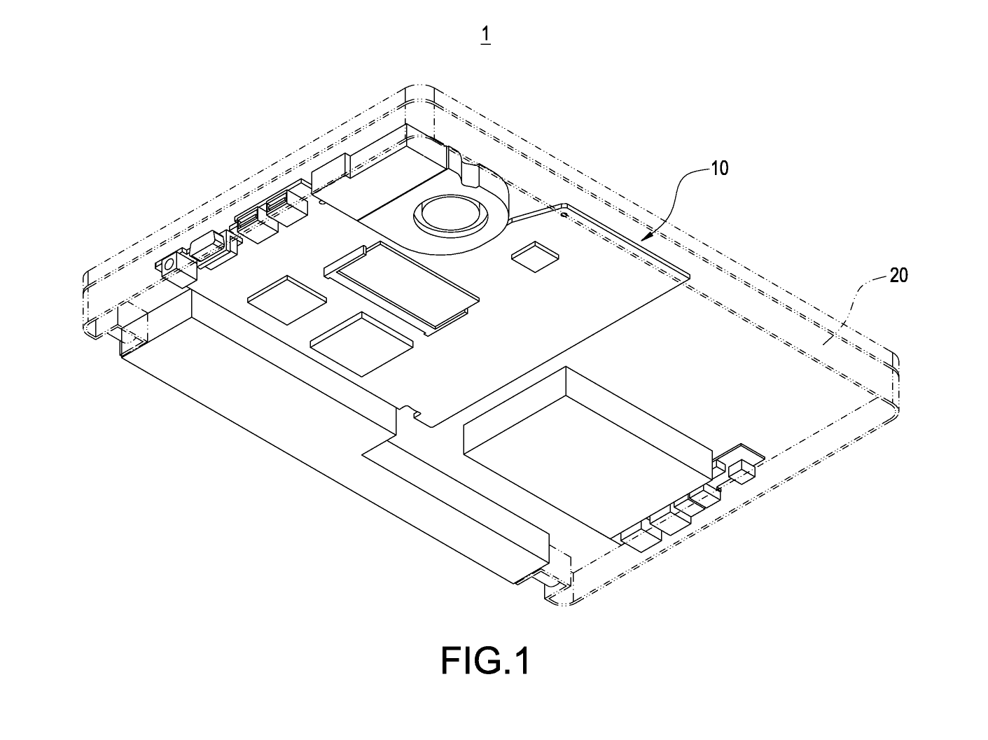

FIG. 1 shows a perspective view of the computer host with the motherboard of the invention. The motherboard 10 is disposed in a housing 20 of the computer host 1. The viewing point is from the bottom of the computer host 1.

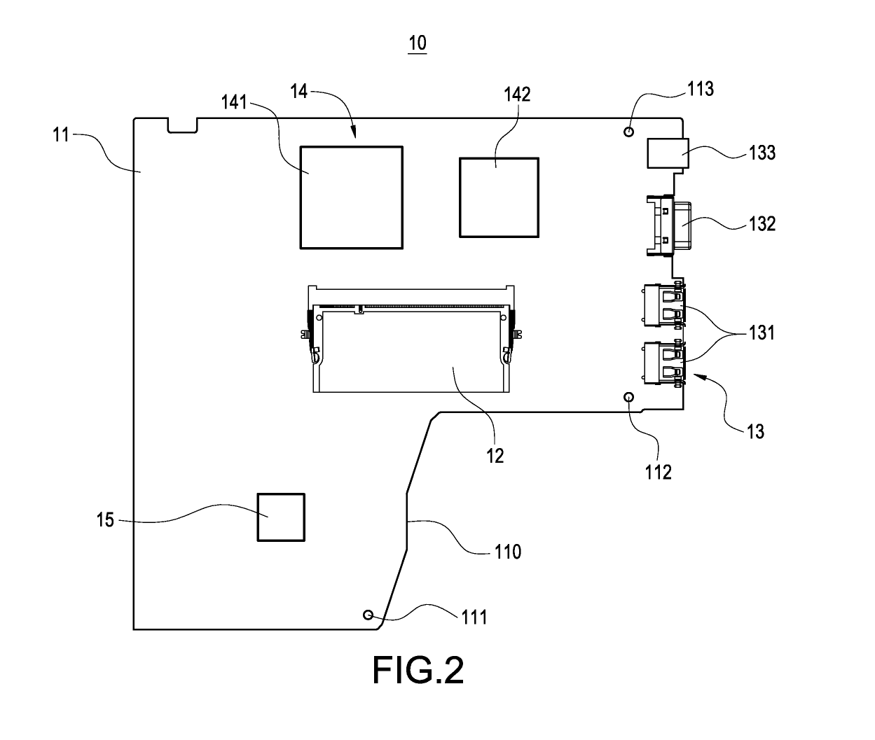

FIG. 2 shows a planar view of the motherboard 10 of the invention. The motherboard 10 includes a circuit board 11, a memory module 12, an first I/O module 13 and a chip module 14.

There is an indention 110 at a corner of the circuit board 11. Two through holes 111, 112 are separately provided near two edges of the indention 110. The memory module 12 is arranged on the circuit board 11 behind the indention 110. The first I/O module 13 is arranged on the right of the memory module 12. The first I/O module 13 includes one or two USB connector 131, a VGA connector 132 and a power jack 133. Another through hole 113 is provided at a corner of the circuit board 11 near the first I/O module 13.

The chip module 14 is arranged far from the indention 110. The chip module 14 includes a CPU 141 and a north bridge chip 142 selectively disposed behind or on the left of the memory module 12. In the shown embodiment of the invention, the chip module 14 is behind the memory module 12. The CPU 141 is disposed at the left behind the memory module 12 and the north bridge 142 is disposed at the right behind the memory module 12. Additionally, a south bridge 15 is disposed in the left portion of the circuit board 11 far from the indention 110.

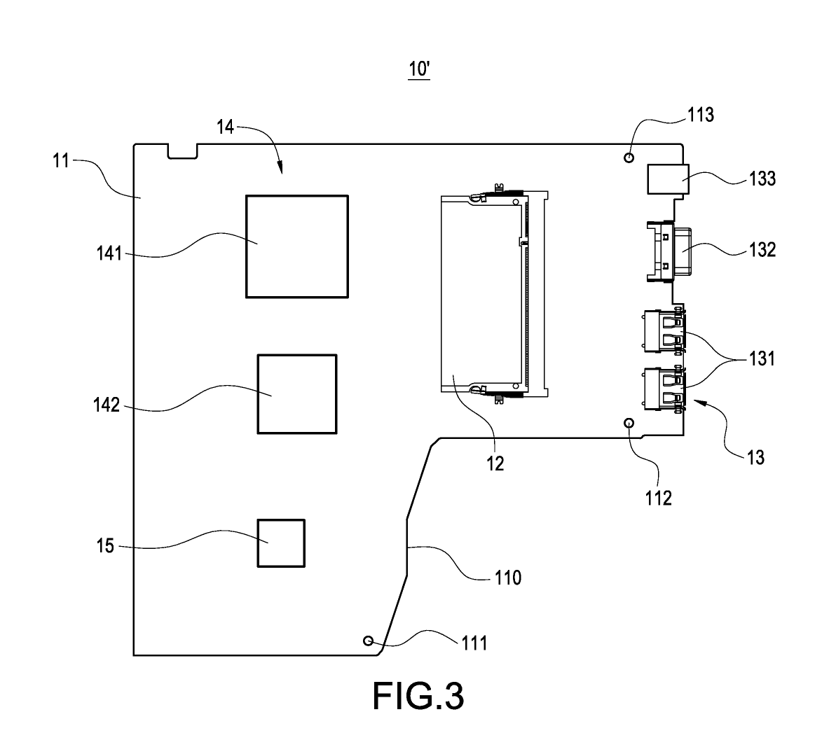

FIG. 3 shows the second embodiment of the motherboard of the invention. In this embodiment, the chip module 14 is arranged at the left of the memory module 12, wherein the CPU 141, the north bridge 142 and the south bridge are arranged in a row.

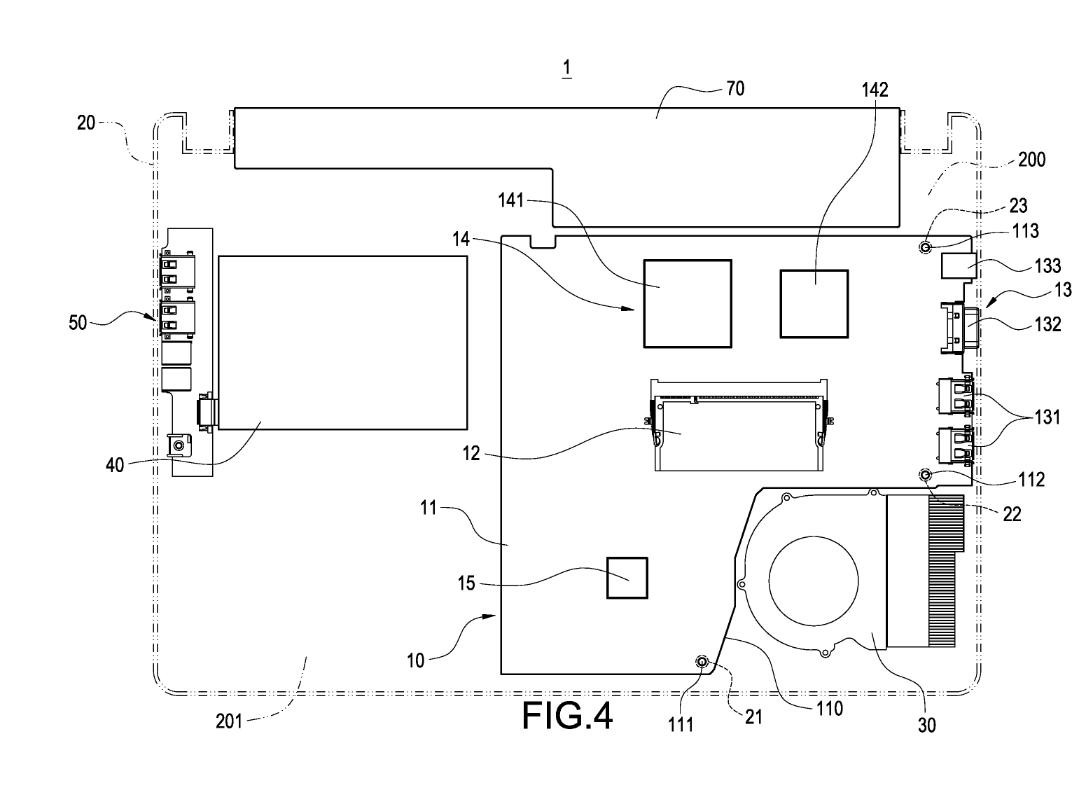

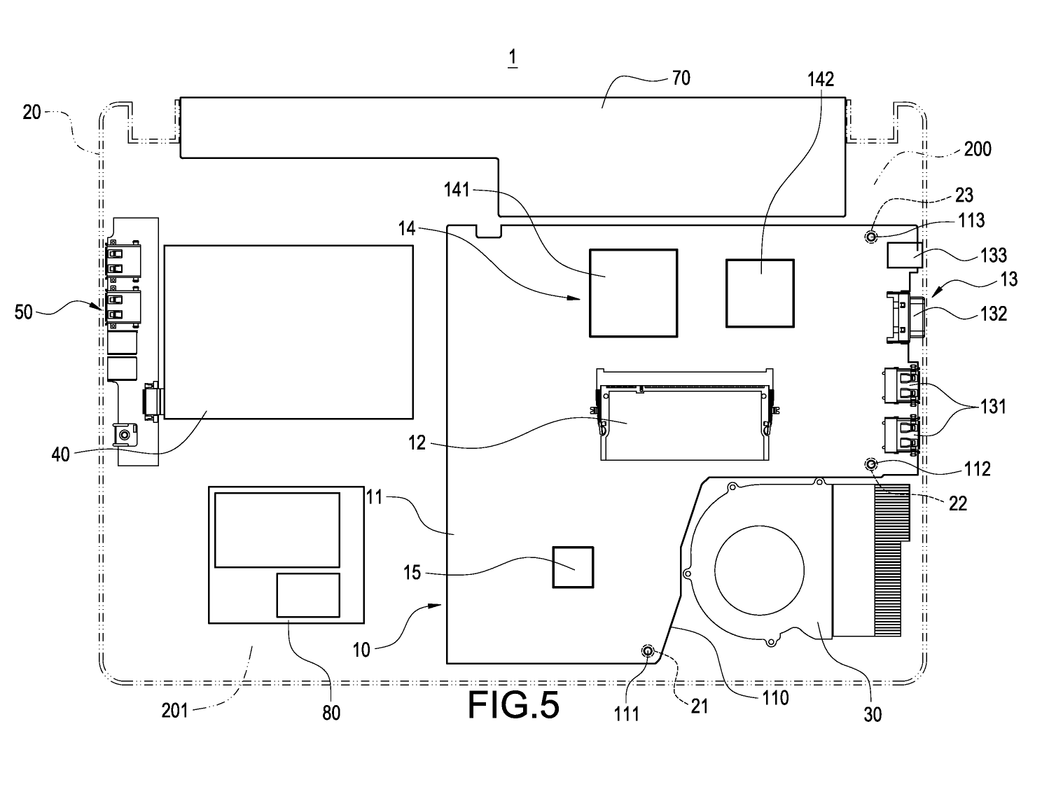

FIGS. 4 and 5 are two planar views of the computer host of the invention. The computer host 1 uses the abovementioned motherboard 10 therein. The computer host 1 includes a housing 20, the motherboard 10 and a heat dissipation unit 30 and a hard disk drive 40.

The housing 20 has a space 200 therein. The right half of the space 200 accommodates the motherboard 10. The housing is provided with three screw rods 21-23 corresponding to the through holes 111-113 of the circuit board 11. Furthermore, the heat dissipation unit 30 is accommodated in the indention 110 of the circuit board 11. The hard disk drive 40 is accommodated in the left half of the space 200.

The left margin of the space 200 is provided with a second I/O module 50. Additionally, the computer host 1 is equipped with a battery module 70 disposed near a side of the motherboard 10 far from the indention 110. A free room 201 is formed at the left of the motherboard 10 and the front of the hard disk drive 40. Referring to FIG. 5, the embodiment shown in the figure is provided with a wireless network module 80 in the free room 201. However, the wireless network module 80 can be changed into any other device under requirements.

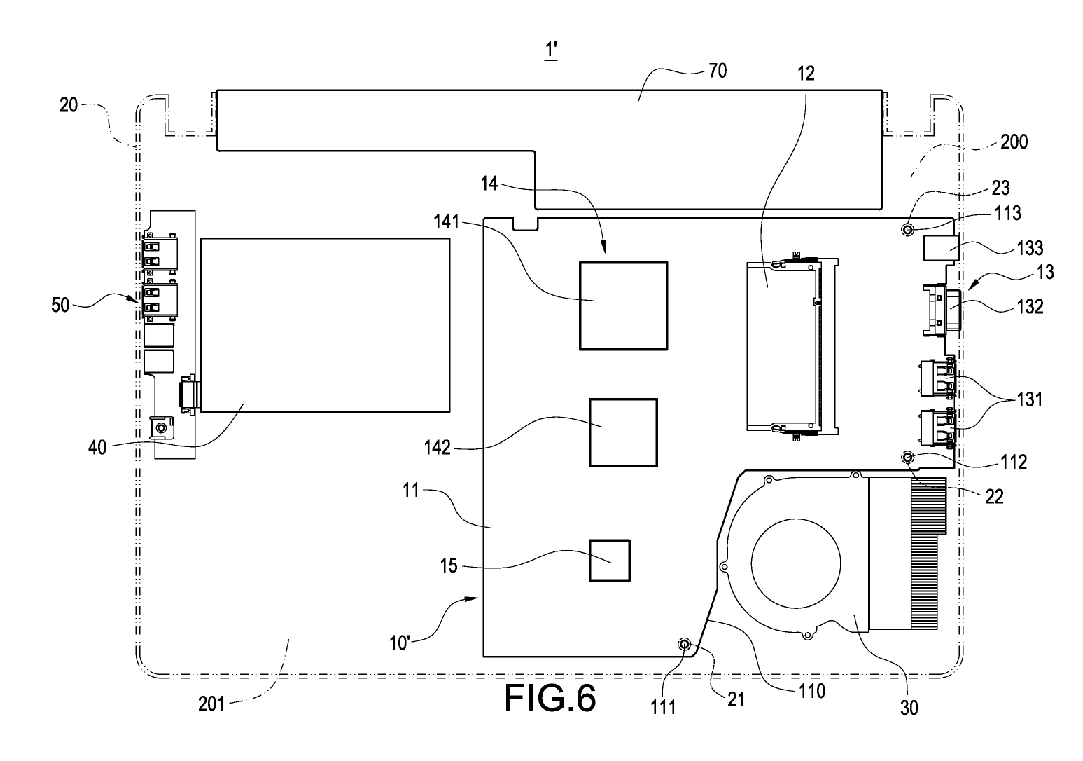

FIG. 6 shows the computer host using the second embodiment of the motherboard of the invention. This embodiment installs the abovementioned second embodiment of the motherboard 10′ to a computer host 1.

Embodiments of the invention have been described. Nevertheless, it will be understood that various modifications may be made without departing from the spirit and scope of the invention. Accordingly, other embodiments are the scope of the following claims.

What is claimed is:

1. An arrangement of motherboard, comprising:
a circuit board having an indention at a corner thereof;
a memory module disposed at a rear position of the indention;
an I/O module disposed at a right position of the memory module and on an edge of the circuit board; and
a chip module disposed on a portion of the circuit board far from the indention and at a left or rear side of the memory module.

2. The arrangement of motherboard of claim 1, further comprising two through holes separately near two edges of the indention.

3. The arrangement of motherboard of claim 2, further comprising another through hole near the I/O module.

4. The arrangement of motherboard of claim 1, wherein the I/O module comprises a power jack, a VGA connector and at least one USB connector.

5. The arrangement of motherboard of claim 1, wherein the chip module comprises a CPU at left of rear of the memory module and a north bridge at right of rear of memory module.

6. The arrangement of motherboard of claim 1, wherein the chip module comprises a CPU at rear of left of the memory module and a north bridge at front of left of memory module.

7. The arrangement of motherboard of claim 1, further comprising a south bridge at a left portion far from the indention of the circuit board.

8. An arrangement of computer host, comprising:
a housing having a space therein;
a motherboard disposed in a right half of the space, comprising:
a circuit board having an indention at a corner thereof;
a memory module disposed at a rear position of the indention;
a first I/O module disposed at a right position of the memory module and on an edge of the circuit board; and
a chip module disposed on a portion of the circuit board far from the indention and at a left or rear side of the memory module.
a heat dissipation unit disposed in the indention; and
a hard disk drive disposed in a left half of the space.

9. The arrangement of computer host of claim 8, further comprising a second I/O module at left of the hard disk drive.

10. The arrangement of computer host of claim 8, further comprising a battery module disposed near an edge of the motherboard far from the indention.

11. The arrangement of computer host of claim 8, wherein a free room is formed at left of the motherboard and at front of the hard disk drive.

12. The arrangement of computer host of claim 11, further comprising a wireless network module disposed in the free room.

13. The arrangement of computer host of claim 8, wherein the circuit board further comprises two through holes separately near two edges of the indention.

14. The arrangement of computer host of claim 13, wherein the housing further comprises 2 screw rods corresponding to the through holes separately.

15. The arrangement of computer host of claim 14, wherein the circuit board further comprises another through hole near the I/O module.

16. The arrangement of computer host of claim 15, wherein the housing further comprises another screw rod corresponding to the another through hole.

17. The arrangement of computer host of claim 8, wherein the I/O module comprises a power jack, a VGA connector and at least one USB connector.

18. The arrangement of computer host of claim 8, wherein the chip module comprises a CPU at left of rear of the memory module and a north bridge at right of rear of memory module.

19. The arrangement of computer host of claim 8, wherein the chip module comprises a CPU at rear of left of the memory module and a north bridge at front of left of memory module.

20. The arrangement of computer host of claim 8, wherein the motherboard further comprises a south bridge at a left portion far from the indention of the circuit board.
